(19) United States
(12) Patent Application Publication
(10) Pub. No.: US 2026/0018206 A1
(43) Pub. Date: Jan. 15, 2026

(54) Memory with Interleaved Preset

(71) Applicant: Rambus Inc., San Jose, CA (US)

(72) Inventors: Wendy Elsasser, Austin, TX (US); Thomas Vogelsang, Jericho, VT (US)

(21) Appl. No.: 18/994,396

(22) PCT Filed: Jul. 31, 2023
(86) PCT No.: PCT/US23/29064

§ 371 Date: Jan. 14, 2025

Related U.S. Application Data
(60) Provisional application No. 63/370,818, filed on Aug. 9, 2022.

(51) Int. Cl. G11C 11/4096; G11C 11/406; G11C 11/4091

(52) U.S. Cl. CPC G11C 11/4096; G11C 11/40603; G11C 11/4091

(57) ABSTRACT

A memory system includes a host controller that issues access commands, including write pattern commands, to a dynamic, random-access memory (DRAM). Local control circuitry and a row-preset circuitry service write-pattern commands to minimize conflict with access transactions, e. In the memory device, local control circuitry and a row-preset circuit service the write-pattern commands in a manner that minimizes interference with normal read and write transactions. Presetting memory to e.g., erase potentially vulnerable data after use is therefore accomplished efficiently and with no or minimal impact on memory bandwidth and speed performance.

### BACKGROUND

Integrated-circuit devices (ICs or “chips”) communicate signals electronically by expressing patterns of symbols as changing levels of voltage and current. In a memory system, for example, a memory controller writes data to a memory by issuing a write command with a memory address and the data, and later reads the data from the memory device by issuing a read command with the correct memory address. Communicating signals consumes power. A considerable portion of the power required to communicate with a memory is expended transmitting the data signals.

### BRIEF DESCRIPTION OF THE DRAWINGS

FIG. 1 depicts a memory system 100 in which a host controller 105 provides access to a DRAM device 110, a memory device, via a communication channel 115 that communicates data signals DQ and command/address signals CA over respective buses or point-to-point connections.

FIG. 2 is a flowchart 200 illustrating a write-pattern (preset) transaction in accordance with one embodiment.

FIG. 3 schematically represents a portion of DRAM device 110 of FIG. 1 in accordance with one embodiment, like-identified elements being the same or similar.

FIG. 4 is a waveform diagram 400 illustrating voltage levels for a preset operation using the components of FIG. 3 and signal designations that correspond to nodes of FIG. 3.

FIG. 5 schematically represents a portion of a DRAM device 500 similar to DRAM device 110 of FIGS. 1 and 3, like-identified elements being the same or similar.

FIG. 6 is a flowchart 600 illustrating how an embodiment of DRAM device 500 of FIG. 5 presets N rows of memory cells 120.

FIG. 7 is a flowchart 700 illustrating a refresh transaction in accordance with one embodiment of DRAM device 500 of FIG. 5.

FIG. 8 depicts three timing diagrams 800, 805, and 810 illustrating how refresh phase one schedules bitline usage to periods in which they are not required for read and write transactions.

FIG. 9 shows four timing diagrams 900, 905, 910, and 925 illustrating different types of memory access in system 100 of FIG. 1.

### DETAILED DESCRIPTION

A memory system includes a host controller that issues access commands, including write-pattern commands, to a memory device. In the memory device, local control circuitry and a row-preset circuit service the write-pattern commands in a manner that minimizes interference with normal read and write transactions. Presetting memory to e.g., erase potentially vulnerable data after use is therefore accomplished efficiently and with no or minimal impact on memory bandwidth and speed performance.

In some embodiments, the memory system includes dynamic, random-access memory (DRAM), which in turn includes arrays of memory cells that store digital values as voltage levels. A DRAM cell has a capacitor that can be charged or discharged to represent a “bit,” a logical one or zero. The charge on the capacitor leaks away and thus must be refreshed periodically to prevent a loss of the stored data. The memory system manages refresh and preset transactions together to preserve data and minimize their impact on DRAM performance.

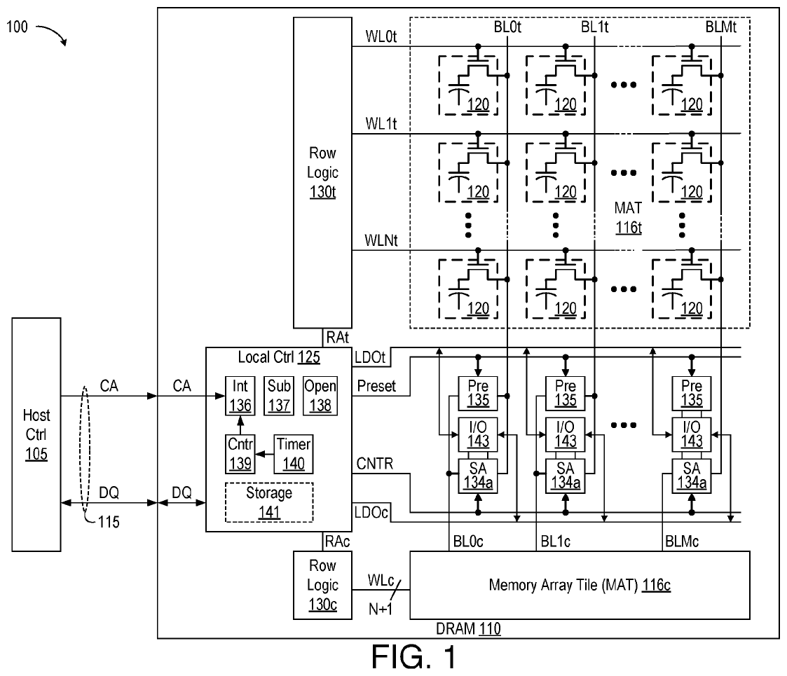

FIG. 1 depicts a memory system 100 in which a host controller 105 provides access to a DRAM device 110 via a communication channel 115 that communicates data signals DQ and command/address signals CA over respective buses or point-to-point connections. DRAM device 110 includes memory-array tiles (MATs) 116t and 116c, each an array with rows and columns of memory cells 120. Local control circuitry 125 responds to commands and addresses CA by issuing control signals RAt and RAc to respective row logic 130t and 130c that selectively assert signals on wordlines WLt[N:0] and WLc[N:0] to “open” a row of memory cells 120, making memory-cell voltages stored therein available on respective bitlines BLt[M:0] and BLc[M:0] to be sensed by stripes of access sense amplifiers 134a. A stripe of input/output (I/O) circuits 143 communicates a row of data to and from local control circuitry 125 via pairs of complementary signals LDOt and LDOc on like-named signal paths. Local control circuitry 125 services access commands using access sense amplifiers 134a (the “a” for “access”) and write-pattern commands using a row of preset circuits 135.

Local control circuitry 125 includes a command interface 136 that receives and interprets commands from host controller 105, a resource-substitution register 137 that maps the addresses of defective memory resources to redundant resources, a refresh-open register 138 that maintains a list of incomplete (open) refresh transactions, a counter 139 that includes the address of a row to be refreshed, and a timer 140 that increments counter 139 to step through the row addresses. Local controller 125 additionally includes optional storage 141 that host controller 105 can load with one or more preset patterns that can then be written to rows of memory cells 120 responsive to subsequent pattern-write (preset) commands. Write patterns can be hard-wired, stored elsewhere, or both in other embodiments. In some embodiments, for example, write-pattern storage is distributed among preset circuits 135. Some embodiments generate random preset patterns. The functions of these elements are described below with emphasis on the interplay between local control circuitry 125 and preset circuits 135.

Host controller 105 and DRAM device 110 are integrated-circuit (IC) devices, commonly referred to as “chips.” Host controller 105 can be a separate, standalone chip, or integrated into another chip. For example, a memory controller may be included on a single die with a microprocessor or included as part of a more complex system such as a system on a chip (SOC). DRAM device 110 includes banks/sub-banks of MATs 116, though only two are shown (116t and 116c) for ease of illustration. Other elements unnecessary for understanding the operation of system 100 are likewise omitted. The upper and lower MATS are respectively labeled 116t and 116c, the “t” and “c” for “true” and “complement.” A cell or array is not permanently true or complement; rather, a “true” cell or array is one being read from or written to, whereas a “complement” is an identical element that serves as a reference.

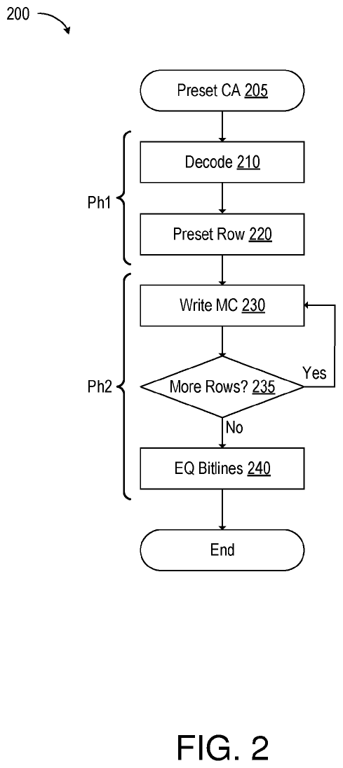

FIG. 2 is a flowchart 200 illustrating a write-pattern (preset) transaction in accordance with one embodiment. The process begins when local control circuitry 125 receives a preset command 205 specifying a row address or range of addresses that are the target of the write-pattern command. The write-pattern transaction is divided into two phases, a first phase Ph1 in which a write pattern is loaded into preset circuits 135 and a second phase Ph2 in which the pattern is copied from presets circuits 135 into a specified row of memory cells 120. The second phase can be repeated for a range of rows if specified by preset command 205.

First phase Ph1 decodes preset command 205 (step 210) and extracts the row address or range of row addresses to be preset. In embodiments that support multiple preset patterns, preset command 205 additionally conveys an address of the selected pattern (e.g., a fixed or programmable register or a row of memory cells 120). In decoding, command interface 136 reviews resource-substitution register 137 for the address to be preset, making an address substitution to a redundant resource if needed. A substitution can likewise be made for the address of the write pattern. Then, in step 220, the preset pattern is loaded into preset circuits 135, one bit in each preset circuit 135 associated with a bitline pair. In some embodiments, preset circuits 135 load the preset pattern into sense amplifiers 134a.

Second phase Ph2 writes the pattern from preset circuits 135 or sense amplifiers 134a into a selected row of memory cells 120 (step 230). Per decision 235, step 230 is repeated for each row of memory cells specified in command 205. When there are no more, the bitlines are then equalized—their voltages are set equal—in anticipation of a subsequent access (step 240). This completes the write-pattern transaction for a given row or rows. The second phase Ph2 can be interrupted at any time to service a normal access request and later completed.

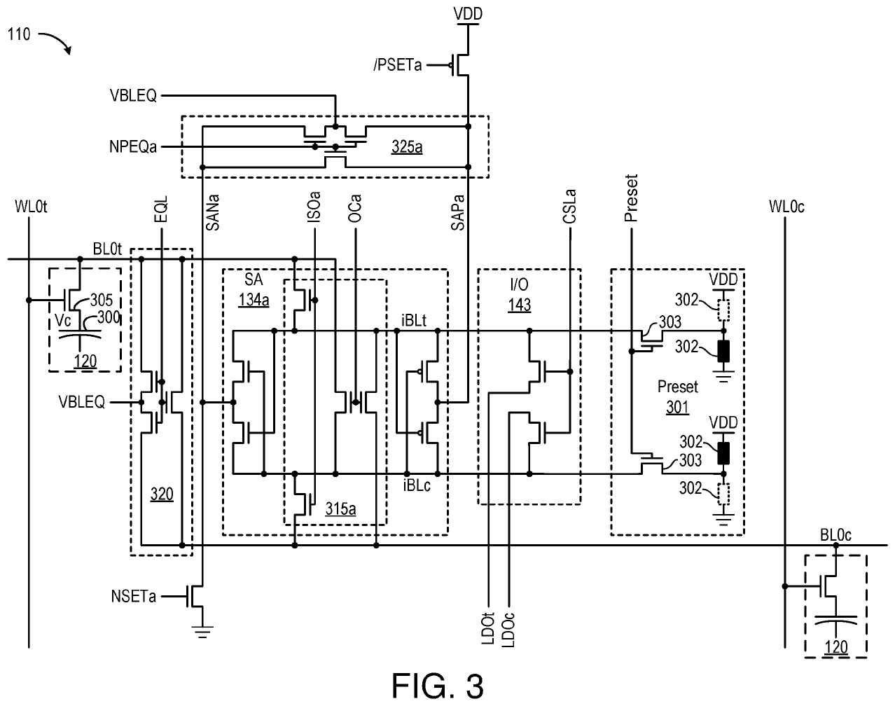

FIG. 3 schematically represents a portion of DRAM device 110 of FIG. 1 in accordance with one embodiment, like-identified elements being the same or similar. Access sense amplifier 134a is selectively coupled between complementary bitlines BL0t and BL0c to detect and amplify voltage differences between bitlines BL0t and BL0c when a one of wordlines WL0t and WL0c is asserted to discharge a capacitor 300 through a transistor 305 and onto the respective bitline, the other bitline serving as a reference. In this example, bitline BL0t is used to read the contents of the leftmost memory cell 120 against reference bitline BL0c. I/O circuit 143 conveys complementary signals LDOt and LDOc to and from internal bitlines iBLt and iBLc to write and read data bits. A preset circuit 301, an embodiment of preset circuit 135 of FIG. 1, can be controlled to load a preset bit into sense amplifier 134, from whence it can then be conveyed to a memory cell 120.

Access sense amplifier 134a includes a pair of cross-coupled inverters switched on by an evaluate control block 315. The cross-coupled inverters comprise n-channel field effect transistors (NFETs) on the left and p-channel field effect transistors (PFETs) on the right. The uppermost NFET/PFET pair form a first inverter that is cross-coupled to a second inverter formed using the lowermost pair. The negative supply voltage SANa and the positive supply voltage SAPa to the inverters are selectively provided when local control circuitry 125 asserts respective control signals NSETa and/PSETa, both of which are part of the control port labeled CNTR in FIG. 1. Signals NSETa and/PSETa are deasserted and signal EQL asserted to allow a bitline-equalization block 320 to equalize the voltage levels on bitlines BLt and BLc between sense operations. A power-supply equalization block 325a likewise equalizes supply lines SANa and SAPa to a common intermediate voltage VBLEQ between sense operations. I/O circuit 143 allows local control circuitry 125, by asserting control signal CSLa, to move complementary data signals LDOt/LDOc to and from bitlines BLt/BLc during a write and read access, respectively. Each control node and signal to access sense amplifier 134a is designated with a trailing “a” for “access.” Signals with a leading “/” are active low, meaning that they are asserted/deasserted as a relatively low/high voltage.

In access sense amplifier 134a, evaluate control block 315a receives an offset cancellation signal OCa and an isolation signal ISOa from local control circuitry 125. The term “offset” refers to characteristic differences between the components of access sense amplifier 134a that can imbalance the amplifier and thus produce sense errors. Asserting signal OCa connects internal bitline nodes iBLt and iBLc to external bitlines BL0c and BL0t, the opposite connectivity employed when isolation signal ISOa is asserted to sense the voltage difference between bitlines BL0t and BL0c. Asserting signal OCa briefly senses the characteristic offset to impose a corresponding voltage offset between bitlines BL0t and BL0c that counteracts the effect of the characteristic offset when signal ISOa is asserted. Deasserting both the OCa and ISOa signals disconnects access sense amplifier 134a from the bitlines BL0t and BL0c.

Preset circuit 301 includes one-time-programmable elements, fuses 302, that can be programmed such that transistors 303 connect internal bitlines iBLt/iBLc to a complementary value expressive of a logic one or a logic zero. The programmable elements can also be e.g. anti-fuses and mask options. In this example, blown fuses 302 are depicted as dashed lines, meaning that preset circuit 301 selectively connects internal bitline iBLt to ground (the low supply voltage) and internal bitline iBLc to VDD (the high supply voltage) when preset signal Preset is asserted. This value is assumed to represent a logic zero but could as easily represent a logic one. To store this preset value in the leftmost memory cell 120, signal Preset is asserted with sense amplifier 134a disconnected from bitlines BL0t and BL0c until the voltage representative of a logic zero is available across internal bitlines iBLt and iBLc. Some or all of this signal development can take place with signal ISOa asserted. Signals ISOa and wordline WL0t are both asserted to write the preset bit from sense amplifier 134a to the leftmost memory cell 120.

Preset circuit 301 can omit one of transistors 303 and related programmable elements 302, allowing just one transistor to impose enough offset between the internal bitlines for error-free sensing. Programmable elements can also be omitted in favor of e.g. a direct connection to a supply node. In one embodiment, for example, a single transistor 303 selectively connects internal bitline iBLt to ground to load a preset bit to sense amplifier 134a. Preset circuit 310 can also be connected to one or both of bitlines BL0t and BL0c rather than via one or both internal bitlines iBLt and iBLc in other embodiments.

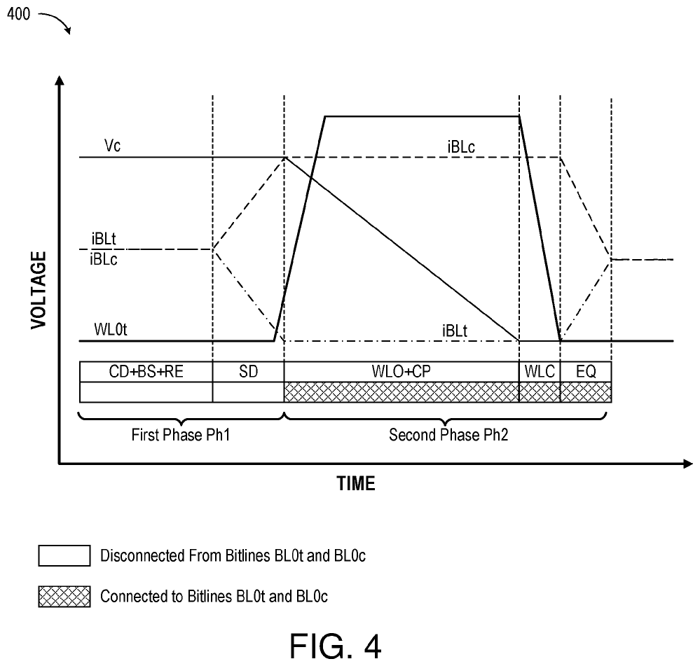

FIG. 4 is a waveform diagram 400 illustrating voltage levels for a preset operation using the components of FIG. 3 and signal designations that correspond to nodes of FIG. 3. Signal Vc refers to a memory-cell voltage across capacitor 300 of the leftmost memory cell 120, a voltage that represents a stored binary value; signals iBLt and iBLc represent voltage levels on complementary internal nodes of amplifier 134a that can be isolated from bitlines BL0t and BL0c via control block 315; and signal WL0t represents the wordline voltage that is raised (asserted) to enable transistor 305 in the memory cell 120 at left in FIG. 3 to share the charge stored on the corresponding capacitor 300 with bitline BL0t and vice versa. Voltage Vc across capacitor 300 is proportional to the stored charge and is initially high, representative of a logic one. In this example voltage Vc is to be preset low.

Labels along the time axis summarize various periods of a preset (write-pattern) transaction. Host controller 105 initiates the transaction by issuing a preset command to local control circuitry 125. During a set-up period, local control circuitry 125 decodes the command (CD=command decode) to determine the type and address of the access. The address allows local control circuitry 125 to select the bank of memory cells (BS=bank select) and perform a redundancy evaluation RE by which local control circuitry 125 can map commands from defective memory resources to redundant resources provided for that purpose. Sense amplifier 134a is powered on by the assertion of signals/PSETa and NSETa and preset signal Preset is asserted to produce a voltage difference across internal bitlines iBLt and iBLc that is amplified by sense amplifier 134a during a period of signal development SD. These operations complete the first phase Ph1 and are accomplished without connecting sense amplifier 134a to bitlines BL0t and BL0c.

In the second phase Ph2, local control circuitry 125 opens the wordline (WLO) by asserting wordline signal WL0t and asserts isolation signal ISOa to initiate cell preset CP in which sense amplifier 134a charges capacitor 300 via bitline BL0t, causing voltage Vc to fall and the voltage on bitline BL0t to rise. Once preset, the wordline closes (WLC) and—assuming the second phase is for the last row to be preset—equalization blocks 320 and 325a are used to equalize the bitlines and the supply nodes of amplifier 134a in preparation for the next access. As noted in a key at bottom left, amplifier 134a is disconnected from bitlines BL0t and BL0c for some periods of the read transaction. These periods can be exploited for refresh transactions that require access to the same bitlines as the preset transaction.

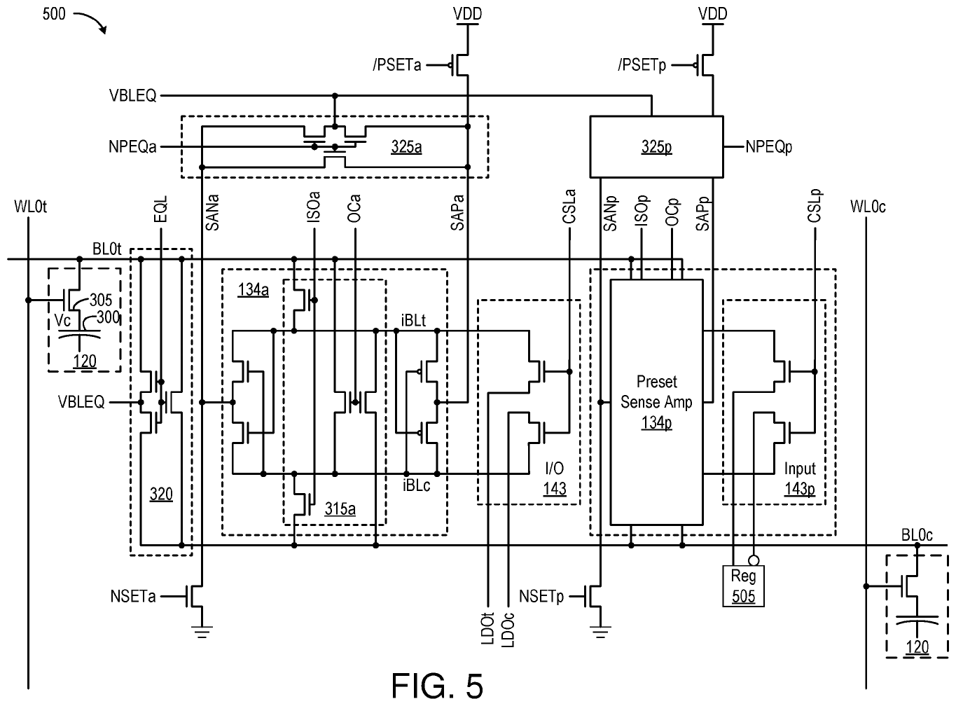

FIG. 5 schematically represents a portion of a DRAM device 500 similar to DRAM device 110 of FIGS. 1 and 3, like-identified elements being the same or similar. A preset sense amplifier 134p, equalization block 325p, and preset input block 143p are added in support of preset and refresh transaction. These elements are identical to the numerical counterparts and distinguished using a suffix “p,” for “preset.” As detailed below, preset sense amplifier 134p also supports reset transactions that are interleaved with normal access transactions to reduce or eliminate interference.

Like access sense amplifier 135a, preset sense amplifier 134p is selectively coupled between complementary bitlines BL0t and BL0c. For preset and refresh, sense amplifier 134p detects and amplifies voltage differences between bitlines BL0t and BL0c in the manner of access sense amplifier 134a to read from and write to rows of memory cells 120. For preset, input block 143p applies the contents of a register 505 to the internal bitlines of preset sense amplifier 134p, which amplifies this complementary preset bit and applies the amplified signal across bitlines BL0t and BL0c. The actions of preset sense amplifier 134p and related elements are independent of access sense amplifier 134a, which allows refresh and preset operations to be interleaved with access transactions. In this embodiment, the preset value zero in register 505 is represented as a low voltage on bitline BL0t and a high voltage on bitline BL0c.

In some embodiments preset sense amplifier 134p is used to generate a random preset pattern. Amplifier 134p is initialized with each bitline at half the bitline voltage and the value sensed with offset-compensation disabled. A row of preset sense amplifiers 134p thus controlled will produce a pattern that depends on the values of the offsets. Amplifiers 134a can likewise be used. Patterns thus generated can be stored for later use or regenerated as needed.

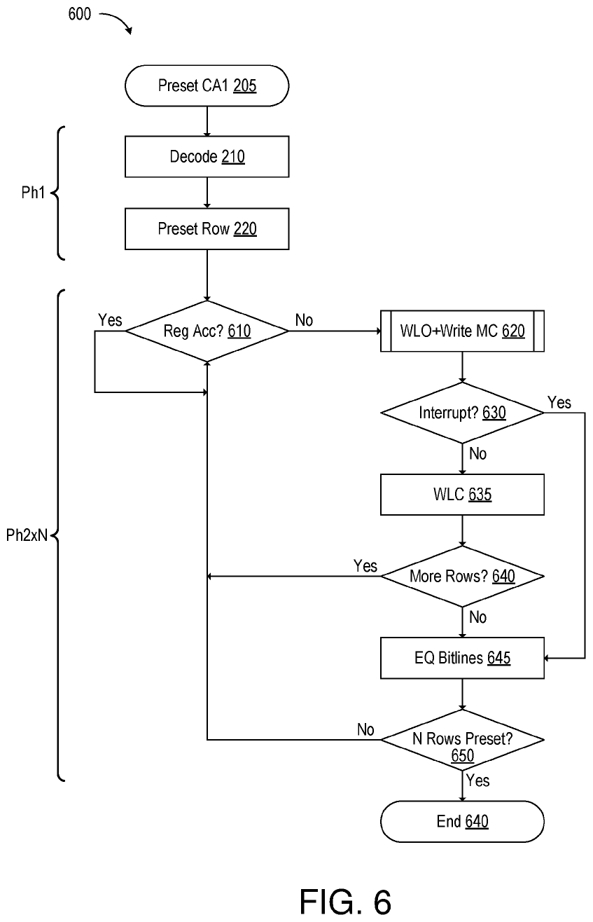

FIG. 6 is a flowchart 600 illustrating how an embodiment of DRAM device 500 of FIG. 5 presets N rows of memory cells 120. As in the example of FIG. 2, this preset transaction includes two phases, a first phase in which a row of preset circuits (a row of preset sense amplifiers 134p in this embodiment) is preset with a write pattern and a second phase Ph2.2 that is repeated for each row to be preset with the write pattern.

As in the example of FIG. 2, the process begins when local control circuitry 125 receives from host processor 105 a preset command 205 specifying a row address or range of N addresses that are the target of the write-pattern command. The write-pattern command is decoded ((step 210) to extract the row addresses to be preset, e.g. a start address and a row offset of N−1 to specify a range of N row address. A write pattern is then loaded into preset sense amplifiers 134p via input circuit 143p from register 505. In other embodiments, local control circuitry controls preset sense amplifier 134p and related circuitry to read the preset pattern from a row of memory cells. In either case, first phase Ph1 ends with the preset pattern stored in a row of preset circuits and ready to be conveyed to the range of N rows of memory cells. The first phase Ph1 is initiated by host controller 105 and thus does not interfere with other commands.

The second phase Ph2×N requires N write transactions responsive to the one preset command from the host. These transactions can be interrupted by subsequent commands from the host so as not to hinder read or write performance. The preset value is preserved in sense amplifiers 134p so preset operations can be interrupted at any time to perform a regular (read or write) transaction during the second phase Ph2 without having to repeat the first phase Ph1 to obtain the preset pattern. Access sense amplifier 134a is used for regular access.

The second phase begins with local control circuitry 125 determining whether a regular access is ongoing (decision 610). If so, the preset transaction is paused until there is a gap in regular accesses. Absent a regular transaction in progress, local control circuitry 125 opens the wordline of the row that this a target of the preset and connects the internal bitline nodes of a row of preset sense amplifiers 134p to the corresponding bitlines (step 620), thereby allowing amplifiers 134p to charge the target row of capacitors with voltages representative of the preset pattern. The preset transaction can be interrupted (decision 630) during step 620 to service a regular access, in which case the bitlines are equalized in preparation for the regular access (step 645). Local control circuitry 125 maintains counts of the interrupted row address and the last row address of the N rows to be preset.

If step 620 proceeds to completion—decision 630 yields a “yes”—local control circuitry 125 closes the wordline (step 635) to disconnect the selected row increments the row address for the next row. If there are no more rows to be preset, decision 640 sends the process to step 645 to equalize the bitlines in preparation for the next transaction. If there are more rows, however, and no ongoing regular access, there is no need to equalize the bitlines because the bitline voltages already express the preset bit to be stored in the next row. If all N rows have been preset, the preset transaction is at an end (decision 650); otherwise, the flow returns to decision 610.

Local control circuitry 125 can alert host controller 105 when a preset transaction is completed, a “transaction” in this context including any number of row operations that write the preset pattern to a row of memory cells responsive to a single preset command. To alert the host, local controller 125 can load a status register (not shown) on DRAM device 110 with a status value to be polled by host controller 105. Such status registers can be provided for each bank in DRAM device 110 to facilitate parallel preset transactions. Local control circuitry 125 can also provide a feedback signal to alert host controller 105 via the main memory interface or a sideband bus (not shown). In some embodiments, the preset protocol for memory system 100 defines a delay from issuance of a memory-preset command to completion and can inhibit normal traffic during this time to minimize the delay. A preset command in some embodiments indicates an inactive period that allows DRAM device 110 to complete e.g. just the first phase and up to a full, multi-row preset transaction. Local control circuitry 125 can require a time window of <n> ns for which a bank being initialized is inactive. This time window can be met within a defined <m> us delay after a memory-preset command is issued.

Returning to FIG. 5, preset sense amplifier 134p additionally supports refresh transactions in this embodiment. Local control circuitry 125 initiates refresh transactions asynchronously with respect to access and write-pattern commands from host controller 105. Refresh transactions are divided into phases and periods that are interleaved with and interrupted by access transactions to minimize access interference, and thereby offer improved memory performance. Refresh transactions can interrupt access transactions, including preset transactions, as needed to avoid loss of data.

A first phase of a refresh transaction senses and stores a bit value from a memory cell; a second phase restores the value to the cell. The first phase of a refresh transaction is divided into periods based upon whether the refresh transaction requires bitline access. Periods of bitline usage are time-shifted and interleaved with access transactions that require the same bitline to read or write data so as not to interfere with access. Access transactions interrupt the second refresh phase, leaving the local control circuitry to attempt cell restoration later when the access transaction or transactions is complete. Preset transactions can operate in the manner of refresh but embodiments with fixed or register storage for preset patterns are more easily interrupted. Preset transactions that rely on a pattern stored in a DRAM row have constraints similar to refresh transactions except that the first phase is timed by the host and thus does not interfere with other host transactions. The host can trigger preset transactions to erase deallocated memory space.

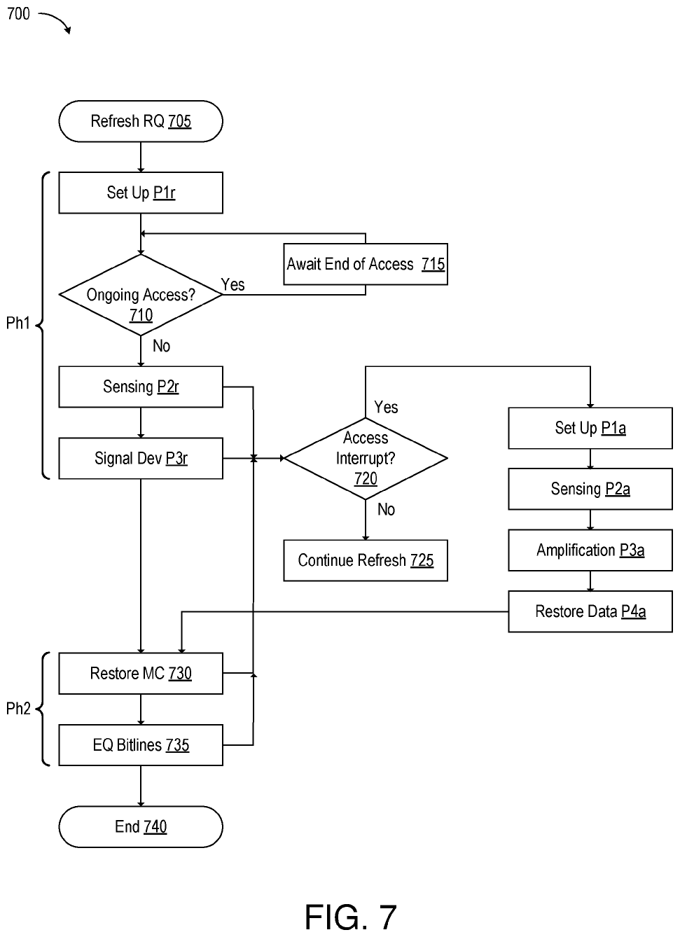

FIG. 7 is a flowchart 700 illustrating a refresh transaction in accordance with one embodiment of DRAM device 500 of FIG. 5. Timer 140 periodically increments causing refresh counter 139 to instigate a refresh transaction. Local control circuitry 125 begins refresh phase one (Ph1) by evaluating the address of the refresh request. The set-up period P1r (for “Period 1, refresh”) does not require bitline access and so does not interfere with any ongoing access transaction. Request interface 136 reviews resource-substitution register 137 for the requested address, making an address substitution to a redundant resource if needed. Local control circuitry 125 then issues a signal, main-wordline falling MWF (not shown), that initiates the assertion of wordline signal WL0t to open the selected memory cell 120.

Per decision 710, if there is an ongoing access transaction using the bitlines required by the refresh request, local control circuitry 125 completes the activity of refresh period P1r and awaits completion of the ongoing access (715). If there is no ongoing access transaction, local control circuitry 125 enters refresh phase one, period two (Ph1, P2r) and senses the memory cells identified during set-up period P1r. Using the example of a read transaction directed to the upper-left memory cell 120 of FIG. 1, wordline WL0t is asserted to connect the capacitor to bitline BL0t, thereby sharing the charge stored on the capacitor with a sense input of preset sense amplifier 134p. The other sense input of amplifier 134p is connected to bitline BL0c, which serves as a reference. With the charge so shared, local control circuitry 125 disconnects preset sense amplifier 134p from bitlines BL0t and BL0c and, in refresh period three P3r, allows preset sense amplifier 134p to amplify the sensed difference between the voltages on bitlines BL0t and BL0c.

The act of sensing destroys the data from the memory cell and retains the sensed value in preset sense amplifier 134p, completing the first phase Ph1 of the refresh transaction. Per decision 720, if local control circuitry 125 receives an access request during signal-development period P3r, local control circuitry 125 interrupts the refresh transaction to tend to the access request. Local control circuitry 125 evaluates access requests to determine whether register 138 indicates the target address is the subject of an open refresh transaction. A write access to an address listed in register 138 proceeds normally and the target address is removed from register 138. For a read access to the memory cell undergoing a refresh transaction, local control circuitry 125 reads the value stored in preset sense amplifier 134p and register 138 maintains the open address. For another memory cell connected to the same bitlines, local control circuitry 125 begins an access set-up period P1a (for “Period 1, access”) during which the access request is evaluated and the bitlines equalized. In the second period P2a, an access sense period, local control circuitry 125 asserts the wordline signal (e.g. WL1t) and connects access sense amplifier 135a to bitlines BL0t and BL0c to allows access sense amplifier 135a to sense the bit voltage representative of a stored value. In amplification period P3a, local control circuitry 125 disconnects access sense amplifier 135a from the bitlines and allows the sensed signal to develop within the access sense amplifier. Once the signal is amplified, local control circuitry 125 enters a restoration period P4a in which it reconnects access sense amplifier 135a to bitlines BL0t and BL0c and opens the requested wordline to restore the voltage in the accessed memory cell. Local control circuitry 125 also reads the accessed data using the corresponding I/O circuit 143a, making that data available to the requesting host. With the access thus completed, local control circuitry 125 issues control signals CNTRa that disconnect access sense amplifier 135a from the bitlines and thus allow refresh phase two Ph2, value restoration, to proceed. The periods of a write transaction are different from those of a read transaction because the data need not be read from the targeted memory cell.

Returning to decision 720, if no access request is received during phase one Ph1, then the refresh transaction is allowed to continue as normal (725). Interrupting phase one Ph1 during sensing period P2r does not interfere with the sensing because the refresh sense operation has time to complete during the set-up phase P1a of the access transaction, a time during which access sense amplifier 135a is decoupled from the bitlines. Interrupting a refresh transaction during signal development P3r does not interfere with phase one of the refresh transaction because signal development does not require preset sense amplifier 134p to be coupled to the bitlines. Refresh transactions can take precedence over preset transactions because preset patterns are not lost during interruptions.

However the process reaches refresh phase two Ph2, preset sense amplifier 134p is reconnected to bitlines BL0t and BL0c and wordlines WL0t reasserted to open the memory cell and restore its contents (730). Bitlines BL0t and BL0c are once again equalized (735), bringing the refresh transaction to an end (740). The act of setting the bitline voltages to a common voltage intermediate between high and low supply voltages is commonly termed “precharging” and readies the bitlines for the next access.

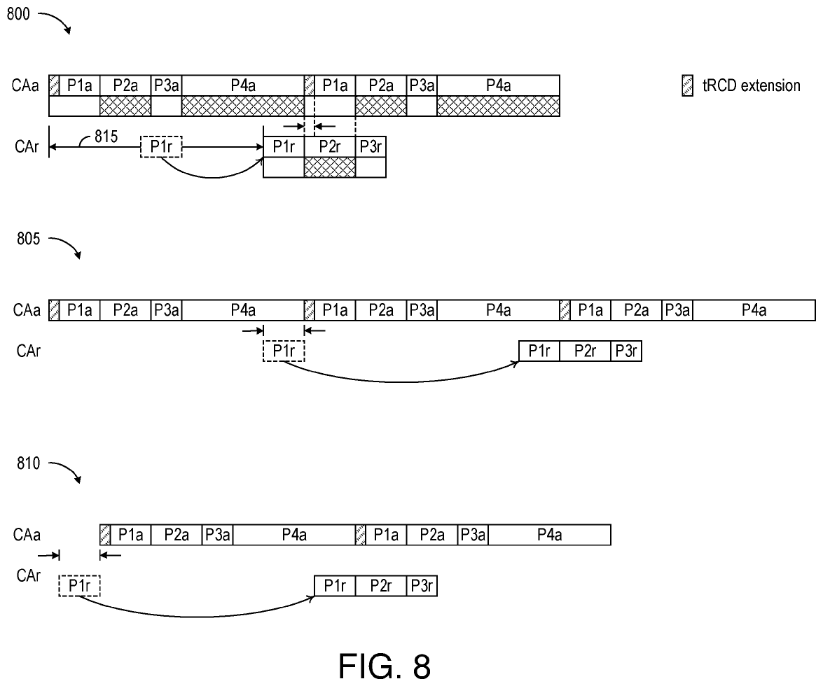

FIG. 8 depicts three timing diagrams 800, 805, and 810 illustrating how refresh phase one schedules bitline usage to periods in which they are not required for read and write transactions. This timing allows refresh transactions to be hidden from host controller 105. The protocol implemented by host controller 105 may require periodic bank-specific pauses to ensure all open refresh transactions have time to complete. The first phase of a preset transaction is timed by the host controller and thus does not require the illustrated time shift.

Access and refresh requests are designated CAa and CAr, respectively. An access request CAa is illustrated as occurring over four periods divided into those that require interaction with bitlines BL0t and BL0c that those that do not. A refresh request CAr, the first phase, is illustrated as occurring over three periods that are likewise divided. The first period of access request CAa, the set-up period P1a during which access commands are decoded, is not as long as sense period P2r of refresh request CAr. Set-up period P1a is extended by a small amount so local control circuitry 125 can time refresh sense period P2r to access bitlines BL0t and BL0c during set-up phase P1a of an access request, a period in which the access transaction is not employing the bitlines. The time extension is labeled a “tRCD extension,” as the datasheet parameter affected by the time extension is the row column delay time which is a function of the time between the access request and the accessed data being available in the access sense amplifier.

Refresh phase 1 is completed after two consecutive regular accesses at the latest. The time required to equalize the bitlines before a regular access in phase 1 is short because it occurs directly after charge sharing, a time during which the bitline voltages are relatively close together. For access transactions, a fast decoding of the bank address and a fast generation of a bank-select signal, illustrated here as period P1a of access request CAa, enables rapid interruption of refresh transactions.

In diagram 800, any refresh request CAr initiated within interval 815—during an access request but before the access request is closing—is aligned with the access request CAa such that sense period P2r does not commence until the bitlines are available after the closing of the access request. Diagram 805 is similar to diagram 800 but the refresh transaction is further delayed because the refresh request arrived too late in the access transaction to complete set-up period P1r before the bitlines are relinquished by the access request. In diagram 810, refresh request CAr arrived before an access request CAa but not in time for refresh request CAr to fully overlap the first part of the subsequent but overlapping access request CAa. The sense period P2r is therefore time shifted so that part two P2r of the refresh request takes place after the access transaction is complete. Set-up period P1r is shown time shifted in diagrams 800, 805, and 810 but can be completed earlier.

Interleaving refresh and access transactions, adding the tRCD extension if needed, accommodates increased refresh rates with little or no impact on the host controller. This technique improves DRAM stability and can be used e.g. to counter row hammer, a security exploit in which certain patterns of access cause charge to leak between cells and possibly change the contents of memory rows that were not addressed in the original memory access.

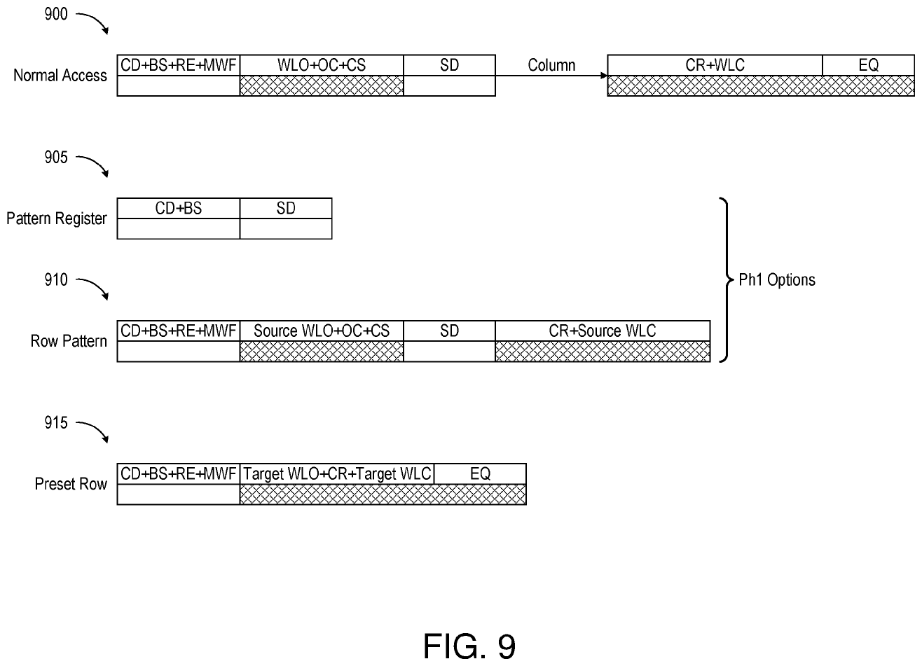

FIG. 9 shows four timing diagrams 900, 905, 910, and 925 illustrating different types of memory access in system 100 of FIG. 1. Diagram 900 illustrates two phases of a normal read access separated by a column operation that conveys a subset of a selected row to host controller 105 via local control circuitry 125. The first phase reads the data from a row of memory cells, a process that destroys the read data, and the second phase refreshes that data in preparation for a subsequent access. Labels along the time axis summarize various periods of the read-access transaction.

Host controller 105 initiates the transaction by issuing a read request, or read command, to local control circuitry 125, which responsively directs control signals CNTRa to manage the transaction. Local control circuitry 125 decodes the command (CD=command decode) to determine the type and address of the access. The address allows local control circuitry 125 to select the bank of memory cells (BS=bank select) and perform a redundancy evaluation RE. Local control circuitry 125 then opens the target wordline (WLO) and controls offset cancellation (OC) and charge sharing (CS) to facilitate signal development (SD) as described previously. A subset of the accessed row of cells 120, a column, is relayed from the corresponding set of access sense amplifiers 135a to local control circuit 125, and from there to host controller 105. In the second phase, charge is restored to the accessed row of memory cells, the wordline is closed, and the bitlines are equalized in preparation for the next access. Each sense amplifier 135a is only connected to bitlines BL0t and BL0c during the periods underscored by shading. The remaining time can be exploited for preset or refresh transactions that require access to the same bitlines.

Diagram 905 illustrates phase one a preset operation in which the preset pattern is read from a pattern register available for that purpose. Command decode CD, bank select BS, and signal development SD are as noted previously, and none requires bitline access. Host controller 105 initiates preset phase 1 by issuing a command that specifies one or more rows.

Diagram 910 illustrates phase 1 of a preset operation in which the preset value is read from a row of memory cells 120. The operation is similar to a refresh operation because the pattern is refreshed in the source row. The host controller can write the preset pattern or patterns to one or more rows. In some embodiments, preset patterns are written to a row or rows in each bank and the preset patterns are shared within each bank.

Diagram 915 represents preset phase two, essentially a write transaction directed to a target row to be preset with the value obtained in preset phase one from a preset register or another row.

Three-dimensional DRAM architectures include layers of memory cells and access transistors in a metal stack. 3D DRAM architectures free up silicon area that can be used to instantiate preset circuitry and related structures.

In the foregoing description and in the accompanying drawings, specific terminology and drawing symbols are set forth to provide a thorough understanding of the present invention. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential, and vice-versa. Similarly, signals described or depicted as having active-high or active-low logic levels may have opposite logic levels in alternative embodiments. As another example, circuits described or depicted as including metal oxide semiconductor (MOS) transistors may alternatively be implemented using bipolar technology or any other technology in which a signal-controlled current flow may be achieved. With respect to terminology, a signal is said to be “asserted” when the signal is driven to a low or high logic state (or charged to a high logic state or discharged to a low logic state) to indicate a particular condition. Conversely, a signal is said to be “de-asserted” to indicate that the signal is charged or discharged to a state other than the asserted state (including a high or low logic state, or the floating state that may occur when the signal driving circuit is transitioned to a high impedance condition, such as an open drain or open collector condition).

The output of the design process for an integrated circuit may include a computer-readable medium, such as, for example, a magnetic tape, encoded with data structures defining the circuitry can be physically instantiated as in integrated circuit. These data structures are commonly written in Caltech Intermediate Format (CIF) or GDSII, a proprietary binary format. Those of skill in the art of mask preparation can develop such data structures from schematic diagrams of the type detailed above.

While the invention has been described with reference to specific embodiments thereof, it will be evident that various modifications and changes may be made thereto without departing from the broader spirit and scope of the invention. Variations of these embodiments will be apparent to those of ordinary skill in the art upon reviewing this disclosure. Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. § 112.

What is claimed is:

1. A memory device comprising:
an array of memory cells, the array of memory cells including rows and columns of memory cells each selectively coupled to a bitline;
a row of access sense amplifiers, each access sense amplifier selectively coupled to one of the bitlines;
storage to store a preset pattern; and
a row of preset circuits coupled to the storage, each preset circuit selectively coupled to one of the bitlines to write one bit of the preset pattern from the storage to one of the memory cells.

2. The memory device of claim 1, wherein each preset circuit is selectively coupled to the one of the bitlines via a corresponding one of the access sense amplifiers.

3. The memory device of claim 1, wherein each preset circuit comprises a preset sense amplifier.

4. The memory device of claim 3, wherein the preset sense amplifier is connected in parallel with the corresponding one of the access sense amplifiers.

5. The memory device of claim 1, wherein the storage comprises a register.

6. The memory device of claim 1, wherein the storage comprises one of the rows of memory cells.

7. The memory device of claim 1, further comprising a control circuit coupled to the preset circuits, the control circuit to control the preset circuits to read the preset pattern from the storage and write the preset pattern from the preset circuit to one of the rows of memory cells.

8. The memory device of claim 7, the control circuit further coupled to the access sense amplifiers to control the sense amplifiers to sense a second pattern from a second row of the memory cells while the preset circuits store the preset pattern.

9. A method for accessing and presetting memory cells in a dynamic, random-access memory (DRAM), the DRAM including rows and column of memory cells and storage for a preset pattern, the method comprising:
receiving a preset command with an address specifying one of the rows of memory cells;
reading the preset pattern from the storage responsive to the preset command; and
writing the preset pattern to the specified row of memory cells.

10. The method of claim 9, wherein the preset command specifies a range of the rows of memory cells, the range including the specified one of the rows of memory cells.

11. The method of claim 10, further comprising writing the preset pattern to all the rows of memory cells within the range of the rows of memory cells responsive to the preset command.

12. The method of claim 9, wherein the storage for the preset pattern comprises ones of the memory cells.

13. The method of claim 12, wherein the storage for the preset pattern comprises one of the rows of memory cells.

14. The method of claim 12, further comprising refreshing the one of the rows of memory cells.

15. A dynamic, random-access memory (DRAM) device comprising:
rows of memory cells; and
local control circuitry to write a preset pattern to a range of the rows of memory cells responsive to a preset command that specifies at least one of the rows of memory cells.

16. The DRAM device of claim 15, further comprising a first row of sense amplifiers coupled to the rows of memory cells and a second row of sense amplifiers coupled to the rows of memory cells, the second row of sense amplifiers to convey the preset pattern to the rows of memory cells.

17. The DRAM device of claim 16, wherein each of the sense amplifiers in the first row of sense amplifiers is connected in parallel, between a pair of bitlines, with one of the sense amplifiers in the second row of sense amplifiers.

18. The DRAM device of claim 15, the local control circuitry to interrupt the write of the preset pattern responsive to an access request.

19. The DRAM device of claim 15, the local control circuity to read the preset pattern from one of the rows of memory cells to write the preset pattern to the range of the rows of memory cells.

20. The DRAM device of claim 15, wherein the rows of memory cells are in a first bank of memory cells and the DRAM device further comprises a second bank of memory cells with second rows of memory cells, the local control circuitry to write a second preset pattern to a second range of the rows of memory cells in the second bank of memory cells.
